(19) United States
(12) Patent Application Publication
(10) Pub. No.: US 2008/0049176 A1
(43) Pub. Date: Feb. 28, 2008

(54) THIN FILM TRANSISTOR-ARRAY SUBSTRATE, TRANSFLECTIVE LIQUID CRYSTAL DISPLAY DEVICE WITH THE SAME, AND METHOD FOR MANUFACTURING THE SAME

(75) Inventors: Hyun Young Kim, Gyeonggi-do (KR); Kwan Wook Jung, Gyeonggi-do (KR); Hyung Don Na, Seoul (KR); Seung Gyu Tae, Gyeonggi-do (KR); Jung Yun Kim, Gyeonggi-do (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/844,873

(22) Filed: Aug. 24, 2007

(30) Foreign Application Priority Data
Aug. 25, 2006 (KR) 10-2006-0080995
Jan. 31, 2007 (KR) 10-2007-0009794

(51) Int. Cl. G02F 1/1335; H01L 21/02; H01L 31/0232

(52) U.S. Cl. 349/114; 257/432; 438/30; 257/E31.124; 257/E21.536

(57) ABSTRACT

A thin film transistor (TFT) array substrate and a transflective LCD device include a gate line and a data line which cross each other; a pixel region which has a transmissive region and a reflective region; a TFT electrically connected to the gate line and the data line; a pixel electrode formed in the pixel region to be electrically connected to the TFT; and a reflective electrode formed in the reflective region, wherein the distance between adjacent pixel electrodes or between the adjacent reflective electrodes with the data line interposed therebetween is in the range of about 3.5 to about 6 μm.

### CROSS-REFERENCE TO RELATED APPLICATION

This application claims priority to Korean Patent Application Nos. 10-2006-0080995, filed on Aug. 25, 2006 and 10-2007-0009794, filed on Jan. 31, 2007, the entire contents of which are incorporated by reference herein.

### BACKGROUND OF THE INVENTION

1. Field of the Invention

The present invention relates to an improved transflective liquid crystal display (LCD) device and a method for manufacturing the same.

2. Description of the Related Art

A typical transflective LCD device has both a transmissive LCD device function and a reflective LCD device function. It uses both light generated by a backlight unit and ambient light, and thus can reduce power consumption.

The transflective LCD device has a reflective region for realizing an image by using ambient light and a transmissive region for realizing an image by using light generated from a backlight unit. Light incident to a reflective region passes through a liquid crystal layer, reflects in a reflective electrode to be redirected to a liquid crystal layer and is externally emitted. Light from a backlight unit incident to a transmissive region passes through a liquid crystal layer to be externally emitted.

However, an electric field is formed between neighboring reflective electrodes which are respectively formed in neighboring pixel regions to affect a liquid crystal layer. For example, an after-image is generated by an electric field between neighboring reflective electrodes formed in reflective regions with a data line interposed therebetween. Also, if an alignment layer for the arrangement of liquid crystal molecules is rubbed in a perpendicular direction to a data line, light leakage occurs around a data line.

### SUMMARY OF THE INVENTION

The present invention provides a transflective LCD device in which light leakage and an after-image are prevented and a method for manufacturing the same.

A first aspect of the present invention provides a thin film transistor (TFT) array substrate comprising: a gate line and a data line which cross each other; a pixel region which has a transmissive region and a reflective region; a TFT electrically connected to the gate line and the data line; a pixel electrode formed in the pixel region to be electrically connected to the TFT; and a reflective electrode formed in the reflective region, wherein the distance between adjacent pixel electrodes or between adjacent reflective electrodes with the data line interposed therebetween is in a range of about 3.5 to about 6 μm.

A second aspect of the present invention provides a transflective liquid crystal display (LCD) device comprising: a first substrate including: a gate line and a data line which cross each other; a pixel region which has a transmissive region and a reflective region; a TFT electrically connected to the gate line and the data line; a pixel electrode formed in the pixel region to be electrically connected to the TFT; and a reflective electrode formed in the reflective region, wherein the distance between the adjacent pixel electrodes or between the adjacent reflective electrodes with the data line interposed therebetween is in the range of about 3.5 to about 6 μm; and a second substrate having a color filter and facing the first substrate with a liquid crystal layer interposed therebetween; and a spacer for maintaining the cell gap between the two substrates, the spacer formed in at least one of the first and second substrates.

The TFT array substrate further comprises a light shielding layer which is formed below the data line to overlap the data line and is wider than the data line.

The light shielding layer is in the range of about 12.5 μm to about 15.5 μm.

The pixel electrode is formed beneath or on the reflective electrode.

A third aspect of the present invention provides a method for manufacturing a transflective liquid crystal display (LCD) device, comprising: preparing a first substrate including a gate line and a data line which cross each other; a pixel region which has a transmissive region and a reflective region; a pixel electrode formed in the pixel region to face an adjacent pixel electrode with the data line interposed therebetween; and a reflective electrode formed in the reflective region, wherein the distance between the adjacent pixel electrodes or between the adjacent reflective electrodes is in the range of about 3.5 to about 6 μm; and preparing for a second substrate having a color filter array and facing the first substrate with a liquid crystal layer interposed therebetween; and forming a spacer for maintaining a cell gap between the two substrates, the spacer formed in at least one of the first and second substrates.

### BRIEF DESCRIPTION OF THE DRAWINGS

The above and other features of the present invention will be described in reference to the attached drawings, in which:

FIG. 1 is a plan view illustrating a transflective LCD device according to an exemplary embodiment of the present invention;

FIGS. 2 and 3 are cross-sectional views illustrating a transflective LCD device according to a first exemplary embodiment of the present invention;

FIG. 4 is a cross-sectional view illustrating a transflective LCD device in which a reflective electrode is formed under a pixel electrode according to the exemplary embodiments of the present invention;

FIGS. 5A and 5B are views illustrating simulation results of driving a liquid crystal layer according to a cell gap according to the exemplary embodiments of the present invention;

FIG. 6 is a cross-sectional view illustrating a transflective LCD device according to a second exemplary embodiment of the present invention;

FIG. 7 is a cross-sectional view illustrating a transflective LCD device in which a black matrix is formed on a color filter array substrate according to the first exemplary embodiment of the present invention;

FIG. 8 is a cross-sectional view illustrating a transflective LCD device in which a black matrix is formed on the color filter array substrate according to the second exemplary embodiment of the present invention;

FIGS. 9A to 15C are plan views and cross-sectional views illustrating a process for manufacturing a TFT array substrate of the transflective LCD devices according to the exemplary embodiments of the present invention, in which FIG. 9A is a plan view illustrating a first mask process for manufacturing the TFT array substrate according to the exemplary embodiments of the present invention, and FIG. 9B is a cross-sectional view taken along line III-III′ of FIG. 9A;

FIG. 10A is a plan view illustrating a second mask process for manufacturing the TFT array substrate according to the exemplary embodiments of the present invention, and FIG. 10B to 10F are cross-sectional views illustrating the second mask process for manufacturing the TFT array substrate according to the exemplary embodiments of the present invention, taken along line III-III′ of FIG. 10A;

FIG. 11A is a plan view illustrating a third mask process for manufacturing the TFT array substrate according to the exemplary embodiments of the present invention, and FIG. 11B is a cross-sectional view taken along line III-III′ of FIG. 11A;

FIG. 12A is a plan view illustrating a fourth mask process for manufacturing the TFT array substrate according to the exemplary embodiments of the present invention, and FIG. 12B is a cross-sectional view taken along line III-III′ of FIG. 12A;

FIG. 13A is a plan view illustrating a fifth mask process for manufacturing the TFT array substrate according to the exemplary embodiments of the present invention, and FIG. 13B is a cross-sectional view taken along line III-III′ of FIG. 13A;

FIG. 14 shows a lower alignment layer 90 formed over the whole surface of the lower substrate 10;

FIGS. 15A to 15C show a single mask process for forming the pixel electrode 80 and the reflective electrode 81; and

FIGS. 16A to 16F are cross-sectional views illustrating the color filter array substrate according to the exemplary embodiment of the present invention.

### DETAILED DESCRIPTION OF THE INVENTION

Reference will now be made in detail to the embodiments of the present invention, examples of which are illustrated in the accompanying drawings, wherein like reference numerals refer to the like elements throughout. The embodiments are described below in order to explain the present invention by referring to the figures.

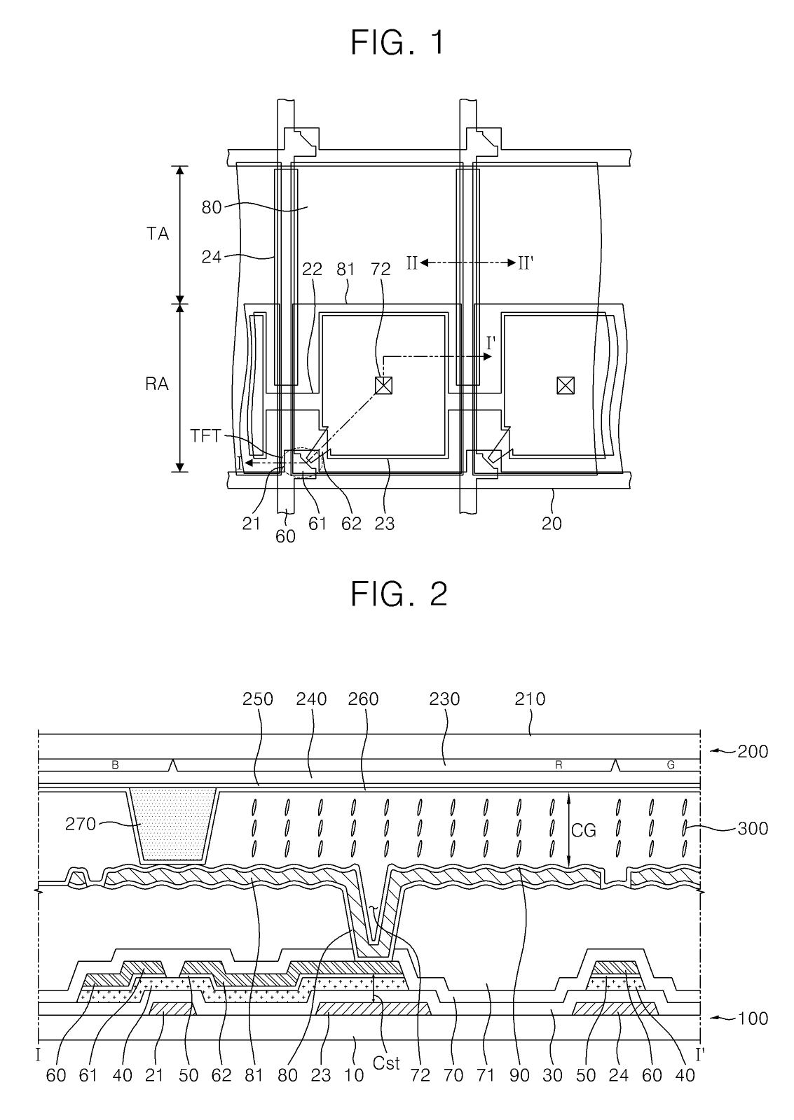

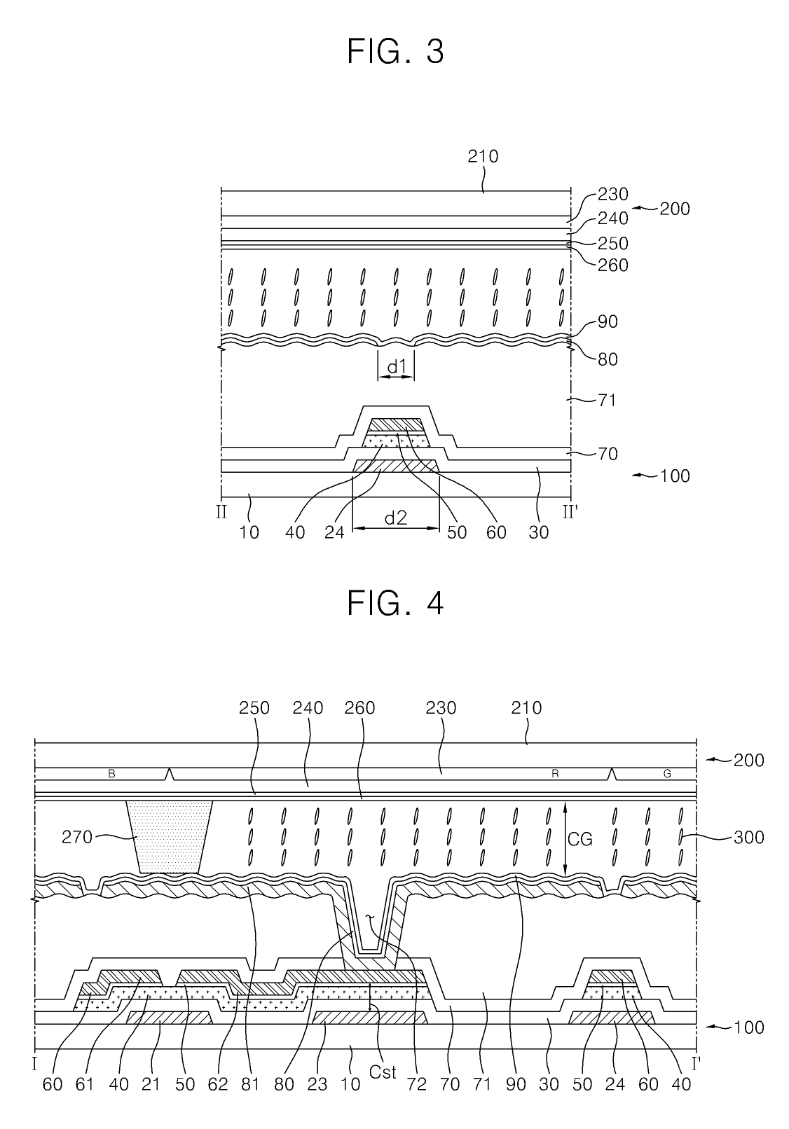

FIG. 1 is a plan view illustrating a transflective LCD device according to an exemplary embodiment of the present invention. FIGS. 2 and 3 are cross-sectional views illustrating a transflective LCD device according to a first exemplary embodiment of the present invention. Here, FIG. 2 is a cross-sectional view taken along line I-I′ of FIG. 1, and FIG. 3 is a cross-sectional view taken along line II-II′ of FIG. 1.

Referring to FIGS. 1 to 3, the transflective LCD device according to the first exemplary embodiment of the present invention includes a thin film transistor (TFT) array substrate 100 and a color filter array substrate 200 with a liquid crystal layer 300 interposed therebetween. The TFT array substrate 100 includes a plurality of pixel regions each of which is divided into a transmissive region TA and a reflective region RA. FIGS. 1 to 3 show a single unit pixel. In the TFT array substrate 100, a pixel electrode 80 is formed in the pixel region and a reflective electrode 81 is formed in the reflective area RA. In the color filter array substrate 200, a color filter layer 230 is formed on an upper substrate 210. The transflective LCD device further includes a spacer 270 for forming a cell gap CG which is filled with liquid crystal molecules in the liquid crystal layer 300.

More specifically, the TFT array substrate 100 includes a gate line 20 formed on a lower substrate 1 in one direction, a gate insulating layer 30 formed over the whole surface of the lower substrate 10 while covering the gate line 20, a data line 60 formed on the gate insulating layer in a perpendicular direction to the gate line 20, a TFT formed in each pixel region to be electrically connected to the gate and data lines 20 and 60, a pixel electrode 80 formed in the pixel region to be electrically connected to the TFT, a reflective electrode 81 formed in the reflective region RA to be electrically connected to the pixel electrode 80, and a storage capacitor CST. The TFT array substrate 100 further includes a light shielding layer 24 which overlaps the data line 60 with the insulating layer 30 interposed therebetween.

The gate line 20 applies a scan signal supplied from a gate driving circuit (not shown) to the TFT.

The data line 60 applies a data voltage supplied from a data driving circuit (not shown) to the TFT. The data line 60 is electrically insulated from the light shielding layer 24 by the gate insulating layer 30 interposed therebetween. As shown in FIGS. 2 and 3, the data line 60 is formed on a semiconductor layer 40 and an ohmic contact layer 50 formed on the gate insulating layer 30.

The gate line 20 and the data line 60 cross each other and the pixel region is divided into the transmissive region TA for transmitting light from a backlight unit (not shown) and the reflective region RA for reflecting ambient light to display an image.

The storage electrode 23 of the storage capacitor CST is formed in the reflective region RA with a relatively large area size. Since the reflective electrode 81 is made of an opaque metal, if the storage electrode 23 is formed over the whole reflective region RA, a storage capacitance of the storage capacitor CST can be increased. The storage electrode 23 is formed to extend to a region adjacent to the gate and data lines 20 and 60. The storage electrode 23 may be formed of the same metal as the gate line 20 on the same plan as the gate line 20.

A storage line 22 is formed in parallel to the gate line 20 and applies a storage voltage to the storage electrode 23. The storage line 22 may be formed of the same metal as the gate line 20 on the same plan as the gate line 20.

The TFT includes a gate electrode 21 extending from the gate line 20, the gate insulating layer 30 formed to cover the gate electrode 21, the semiconductor layer 40 formed on the gate insulating layer to overlap the gate electrode 21, a source electrode 61 formed to be connected to the data line 60 above the semiconductor layer 40, a drain electrode 62 formed above the semiconductor layer 40 to face the source electrode 61, and an ohmic contact layer 50 formed between the semiconductor layer 40 and each of the source and drain electrodes 61 and 62. The drain electrode 62 extends to the reflective region RA to overlap the storage electrode 23, with the gate insulating layer 30, the semiconductor layer 40 and the ohmic contact layer 50 interposed therebetween.

A pixel contact hole 72 is formed to penetrate inorganic and organic passivation layers 70 and 71 which cover the TFT, exposing a portion of the drain electrode 62. The pixel electrode 80 is electrically connected to the exposed portion of the drain electrode 62 via the pixel contact hole 72. The pixel electrode 80 is formed over the whole pixel region. Preferably, the distance d1 between the two adjacent pixel electrodes 80 is in the range of about 3.5 μm to about 6 μm.

If the distance d1 between the pixel electrodes 80 is less than about 3.5 μm, signal interference may occur between the adjacent pixel electrodes 80. In this instance, a liquid crystal layer may be abnormally driven in an edge of the adjacent pixel electrodes 80, leading to light leakage. Also, if the distance d1 between the pixel electrodes 80 is less than about 3.5 μm, the pixel electrode 80 may partially overlap the data line 60, so that light leakage may occur in the region where the data line 60 and the pixel electrode 80 overlap because of abnormal liquid crystal driving.

If the distance d1 between the adjacent pixel electrodes 80 is more than about 6 μm, the aperture ratio may be reduced. For these reasons, the distance d1 between the adjacent pixel electrodes 80 is preferably in a range of about 3.5 μm to about 6 μm.

When an organic passivation film 71 is formed having a thickness of several micrometers (μm), signal interference with the data line 60 does not occur, whereby the pixel electrode 80 and the data line 60 are formed to partially overlap. Also, the pixel electrode 80 may be formed to partially overlap the light shielding layer 24 to thereby improve the aperture ratio. In order to improve the characteristics of the TFT, the inorganic passivation film 70 may be further formed below the organic passivation film 71. Preferably, the surface of the organic passivation film 71 is embossing-processed as shown in FIGS. 2 and 3, thereby increasing light reflectivity in the reflective region RA.

The reflective electrode 81 reflects ambient light coming through the color filter array substrate 200 toward the color filter array substrate 200. The reflective electrode 81 is formed by depositing an opaque conductive metal material in the reflective region RA. The transmissive region TA exists where the reflective electrode 81 is not formed. The reflective electrode 81 may be made of the same conductive metal material as the gate line 20 or the data line 60, such as aluminum (Al), an Al alloy, molybdenum (Mo), a Mo alloy, or tungsten (W). The reflective electrode 81 is formed on the pixel electrode 80. The distance d1 between the two adjacent reflective electrodes 81 is preferably in the range of about 3.5 μm to about 6 μm. Therefore, the electric field between the adjacent reflective electrodes 81 formed in the adjacent pixel regions is reduced, thereby preventing abnormal driving of the liquid crystal layer 300.

The light shielding layer 24 is formed on the lower substrate 10 to overlap the data line 60, with the gate insulating layer 30 interposed therebetween, preventing light leakage which occurs at the sides of the data line 60. Preferably, the light shielding layer 24 is wider than at least the data line 60, and more preferably it has a width of about 12.5 μm to about 15.5 μm. The light shielding layer 24 may overlap the semiconductor layer 40 and the ohmic contact layer 50 formed on the gate insulating layer 30. The light shielding layer 24 is formed to be electrically insulated from the storage line 22.

The width of the light shielding layer 24 depends on the distance d1 between the adjacent pixel electrodes 80 and between the adjacent reflective electrodes 81 respectively formed in the adjacent pixel regions. For example, if the distance d1 between the adjacent pixel electrodes 80, and between the reflective electrodes 81 of the adjacent pixel regions is about 3.5 μm, the width d2 of the light shielding layer 24 is about 12.5 μm, and if the distance d1 between the adjacent pixel electrodes 80 and between the reflective electrodes 81 of the adjacent pixel regions is about 6 μm, the width d2 of the light shielding layer 24 is about 15.5 μm, thereby preventing the momentary after-image caused by light leakage.

Alternatively, as shown in FIG. 4, the reflective electrode 81 may be formed between the pixel electrode 80 and the organic passivation film 71.

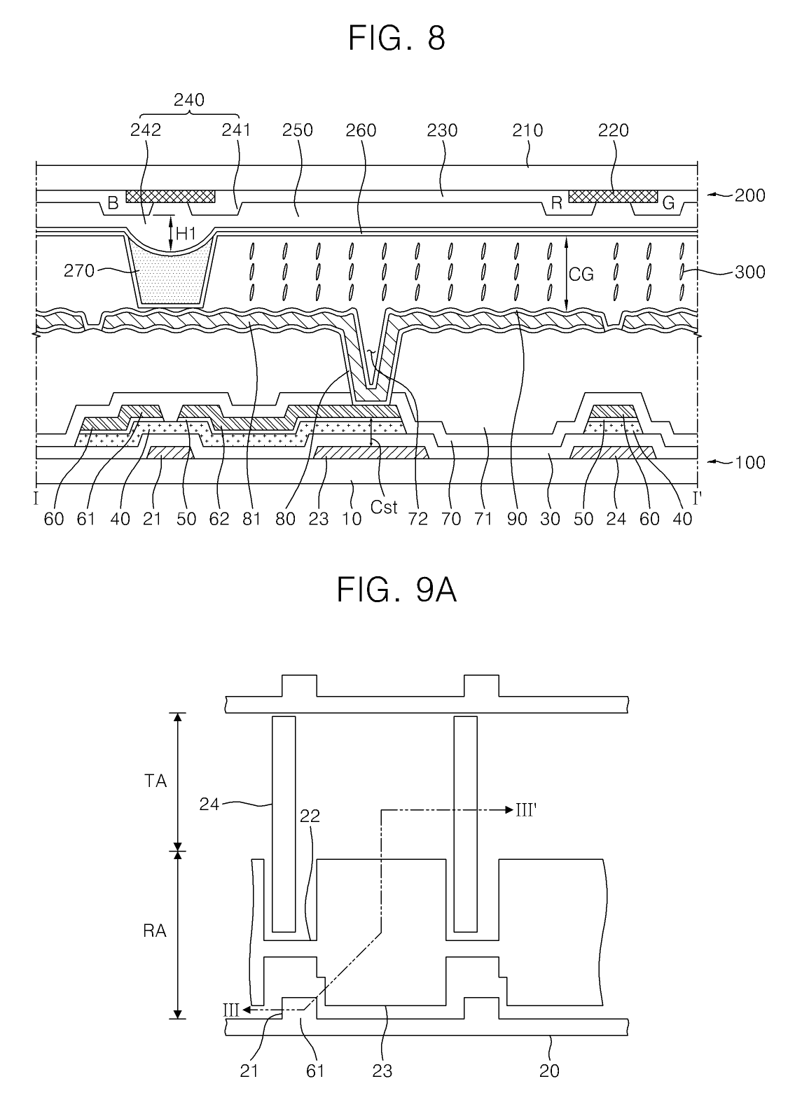

The color filter array substrate 200 includes a color filter layer 230 formed on an upper substrate 210, an overcoat layer 240 formed on the color filter layer 230, and a common electrode 250 formed on the overcoat layer 240. The color filter array substrate 200 may further include a black matrix (see 220 in FIGS. 7 and 8) for preventing light leakage. In more detail, the color filter layer 230 includes red (R), green (G) and blue (B) color filters each of which are formed corresponding to respective pixel regions. The R, G and B color filters generate R, G and B colors by absorbing or transmitting light of a certain wavelength through R, G and B pigments contained therein, respectively. At this time, various colors can be realized by an additive color mixture of the R, G and B light which pass through the R, G and B color filters. The R, G and B color filters may be arranged in a stripe form. That is, the R, G and B color filters may be arranged in line. The color filter may be formed to partially overlap the neighboring color filter formed in the neighboring pixel region. Otherwise, the color filter may be formed within the pixel region not to partially overlap the neighboring color filter, so that an empty space may be formed between the two adjacent color filters.

The overcoat layer 240 serves to planarize the color filter layer 230. If the common electrode 250 is formed directly on the color filter 230, a step difference is generated in an overlapped region of the adjacent color filters where the adjacent color filters overlap each other or in an empty space between the adjacent color filters where the adjacent color filters are separated from each other. Such a step difference causes an electric field to be distorted. The overcoat layer 240 planarizes the color filter layer 230 having the overlapped portion or the empty space between the color filters230, thereby preventing abnormal driving of the liquid crystal layer 300.

The common electrode 250 serves to apply a common voltage to the liquid crystal layer 300 when a data voltage is applied to the pixel electrode 80. The common electrode 250 is made of a transparent conductive material with high transmissivity such as indium tin oxide (ITO), tin oxide (TO) or indium zinc oxide (IZO).

A column spacer 270 is formed in either of the upper and lower substrates 210 and 10. If the column spacer 270 is formed in the upper substrate 10, it is formed to overlap the overlapped portion or the empty space between the color filters, whereas if the column spacer 270 is formed in the lower substrate 10 is formed to overlap the opaque metal line, e.g., the gate and data lines 20 and 60. The column spacer 270 may be formed in the region which overlaps the TFT as well as the gate line 20 and the data line 60. In the exemplary embodiment of the present invention, the column spacer 270 is formed in the upper substrate 210 to overlap the TFT as shown in FIG. 2.

The column spacer 270 may have various forms such as a circular truncated cone or a truncated pyramid.

The column spacer 270 is preferably formed at the same height as the cell gap CG. That is, the column spacer 270 is preferably formed at the height of about 3.5 μm to about 4.0 μm.

Upper and lower alignment layers 260 and 90 are formed in the color filter array substrate 200 and the TFT array substrate 100 for arrangement of the adjacent liquid crystal molecules. The upper and lower alignment layers 260 and 90 pre-tilt liquid the crystal molecules at a predetermined angle θ in order to improve the response speed of the liquid crystal layer 300. Preferably, a pre-tilt angle θ is at least equal to or more than 6°.

If the pre-tilt angle θ is less than 6°, light leakage may occur. For example, if the alignment layers 90 and 260 are rubbed in a 3'oclock direction or in a 9'oclock direction, i.e., in a perpendicular direction to the data line 60, an after-image occurs due to light leakage around the data line 60 such light leakage can be prevented by maintaining the pre-tilt angle θ of equal to or more than 6°.

The upper and lower alignment layers 260 and 90 may be rubbed in a direction depending on the main viewing angle. Preferably, the upper and lower alignment layers 260 and 90 are rubbed in a parallel direction to the data line 60. In this instance, an abnormal driving of the liquid crystal layer 300 can be prevented due to a step difference formed by the distance d1 between the adjacent pixel electrodes 80 and between the reflective electrodes 81 which partially overlap the data line 60. However, even though the upper and lower alignment layers 260 and 90 are rubbed in a perpendicular direction to the data line 60, light leakage can be reduced if the distance d1 between the adjacent pixel electrodes 80 and between the adjacent reflective electrodes 81 with the data line 60 interposed therebetween is about 3.5 μm to about 6 μm. Also, light leakage can be prevented by the light shielding layer 24.

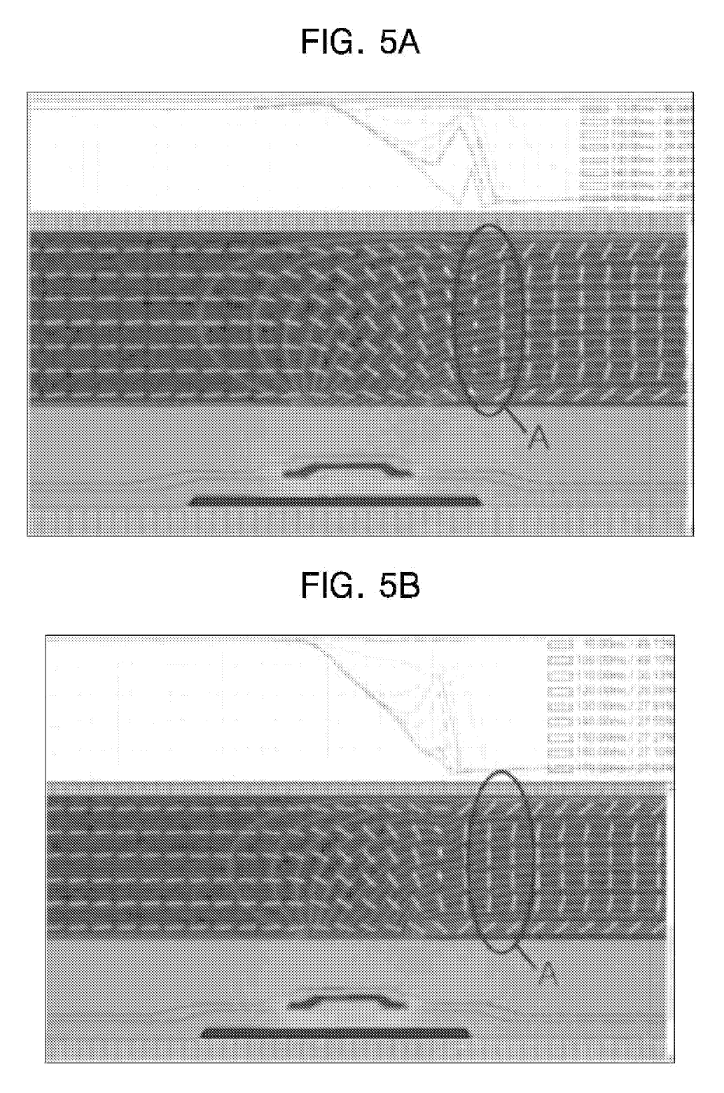

FIG. 5A is a simulation view illustrating a state of the liquid crystal layer after black data are applied to a right pixel when the distance d1 between the adjacent pixel electrodes 80 or between the adjacent reflective electrodes 81 is about 4.0 μm, the width of the light shielding layer 24 is about 12.5 μm and the cell gap CG is about 4.4 μm. FIG. 5B is a simulation view illustrating a state of the liquid crystal layer after black data are applied to a right pixel when the distance d1 between the adjacent pixel electrodes 80 or between the adjacent reflective electrodes 81 is about 4.0 μm, the width of the light shielding layer 24 is about 12.5 μm and the cell gap CG is about 3.6 μm. Referring to FIGS. 5A and 5B, the liquid crystal molecules abnormally driven in a region A is not covered by the light shielding layer 24 when the cell gap is about 4.4 μm as shown in FIG. 5A, whereas the liquid crystal molecules abnormally driven in a region A is covered by the light shielding layer 24 when the cell gap is about 3.6 μm as shown in FIG. 5B. For this reason, the cell gap CG of about 3.5 μm to about 4.0 μm is preferable.

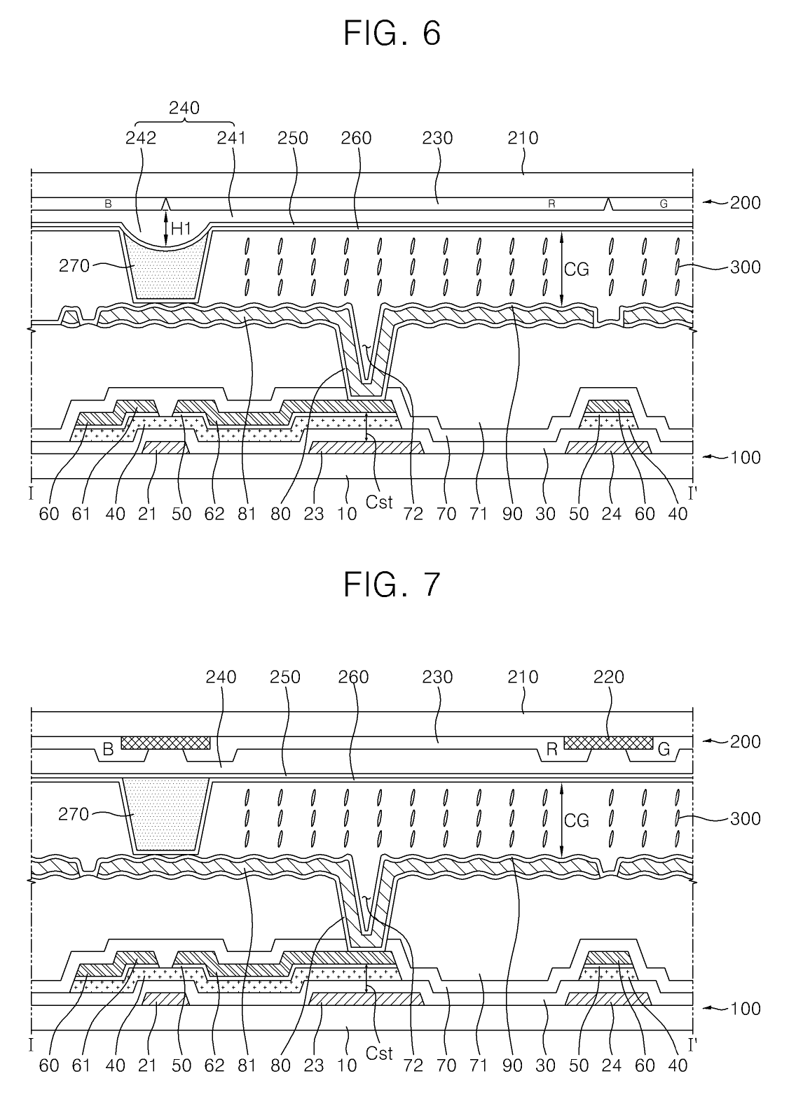

FIG. 6 is a cross-sectional view illustrating a transflective LCD device according to a second exemplary embodiment of the present invention, which is taken along line I-I′ of FIG. 1. The transflective LCD device of FIG. 6 has similar elements to that of FIG. 2 except that an overcoat layer 240 has a step portion or a convex portion, and thus duplicated descriptions on the similar elements are omitted. In FIGS. 2 and 6, like reference numerals denote like parts.

Referring to FIG. 6, a color filter array substrate 200 includes a color filter layer 230 formed on the upper substrate 210, an overcoat layer 240 formed on the color filter layer 230, and a common electrode 250 formed on the overcoat layer 240. The overcoat layer 240 includes a first overcoat portion 241 and a second overcoat portion 242. The second overcoat portion 242 is formed corresponding to the location where a column spacer 270 is to be formed. The sum of the thicknesses of the second overcoat portion 242 and the column spacer 270 is preferably about 0.3 μm smaller than the cell gap CG. The thickness of an upper alignment layer 260 is preferably equal to or less than about 0.1 μm, and the thickness of the common electrode 250 is preferably equal to or less than about 0.2 μm. For example, if the cell gap CG is about 3.9 μm, a thickness sum of the second overcoat portion 242 and the column spacer 270 is about 3.6 μm.

For example, if the column spacer 270 has a height of about 2.1 μm, the second overcoat portion 242 has a height H1 of about 1.5 μm, and if the column spacer 270 has the height of about 1.7 μm, the second overcoat portion 242 has a height H1 of about 1.9 μm. Preferably, the height of the second overcoat portion 242 is equal to or less than about 2 μm. If the second overcoat portion 242 has a height of more than about 2 μm, the second overcoat portion 242 flows along the step portion, so that the liquid crystal molecules in a region where the second overcoat portion 242 flows may be abnormally driven.

The color filter array substrate of the transflective LCD devices according to the first and second exemplary embodiments of the present invention may further include a black matrix.

The transflective LCD devices of FIGS. 7 and 8 have a similar configuration to those of FIGS. 2 and 6, respectively, and a duplicated description on the similar configuration is omitted.

As shown in FIGS. 7 and 8, a plurality of black matrixes 220 are formed on the upper substrate 210 in a matrix form to define color filter regions in which the color filters are to be formed. The black matrix 220 is formed to overlap the gate line 20, the data line 60 and the TFT formed in the TFT array substrate 100. The black matrix 220 shields light transmitted by an undesired liquid crystal arrangement, thereby improving a contrast ratio of the transflective LCD device. The black matrix 220 is made of an opaque metal or an opaque inorganic material.

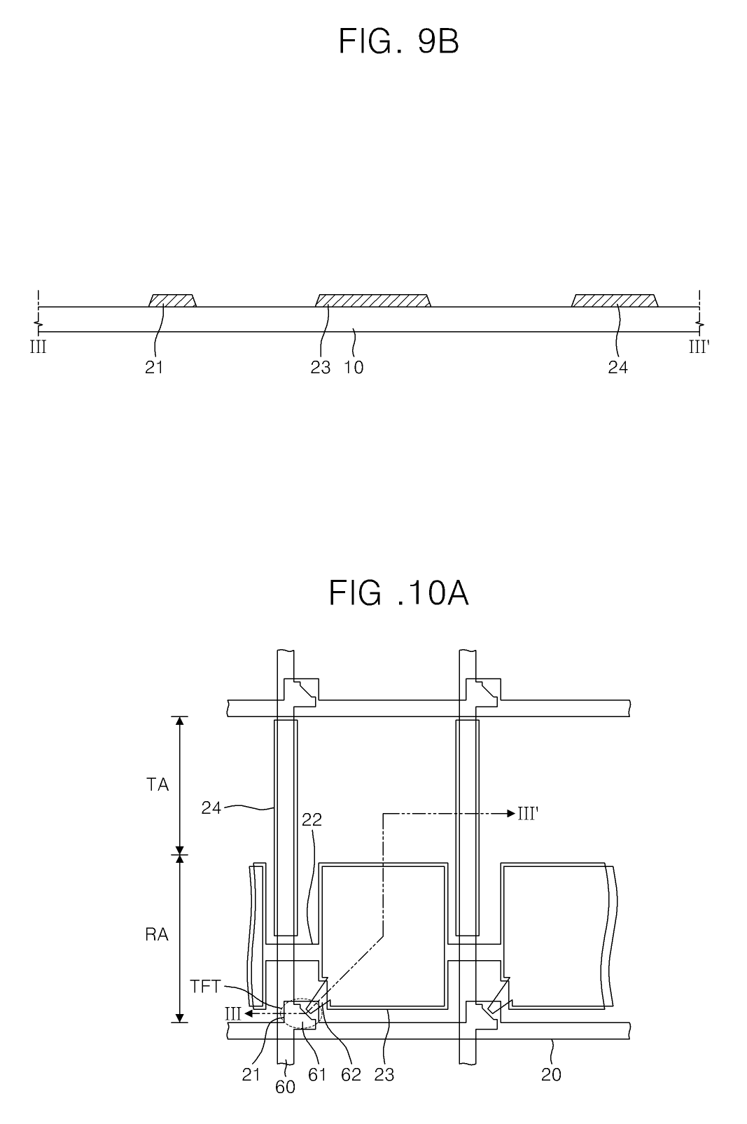

FIGS. 9A to 15C are plan views and cross-sectional views illustrating a process for manufacturing the TFT array substrate of the transflective LCD devices according to the exemplary embodiments of the present invention.

FIG. 9A is a plan view illustrating a first mask process for manufacturing the TFT array substrate according to the exemplary embodiments of the present invention, and FIG. 9B is a cross-sectional view taken along line III-III′ of FIG. 9A.

Referring to FIGS. 9A and 9B, a gate pattern is formed on a lower substrate 10 through a first mask process. The lower substrate 10 is preferably made of a transparent material such as glass or plastic. The gate pattern includes a gate electrode 21, a gate line 20 electrically connected to the gate electrode 21, a storage line 22 formed in parallel to the gate line 20, and a storage electrode 23 electrically connected to the storage line 22.

More specifically, a gate metal layer is formed on the lower substrate 10 by using a sputtering technique or a metal deposition technique. The gate metal layer has a single layer structure or a multi-layer structure made of a metal material such as molybdenum (Mo), titanium (Ti), copper (Cu), aluminum nitride (AlNd), aluminum (Al), Chromium (Cr), a Mo alloy, a Cu alloy, and an Al alloy. By a photolithography process and an etching process using a first mask, the gate metal layer is patterned into the gate pattern including the gate electrode 21, the gate line 20, the storage line 22, and the storage electrode 23. The storage electrode 23 is formed in the reflective region RA.

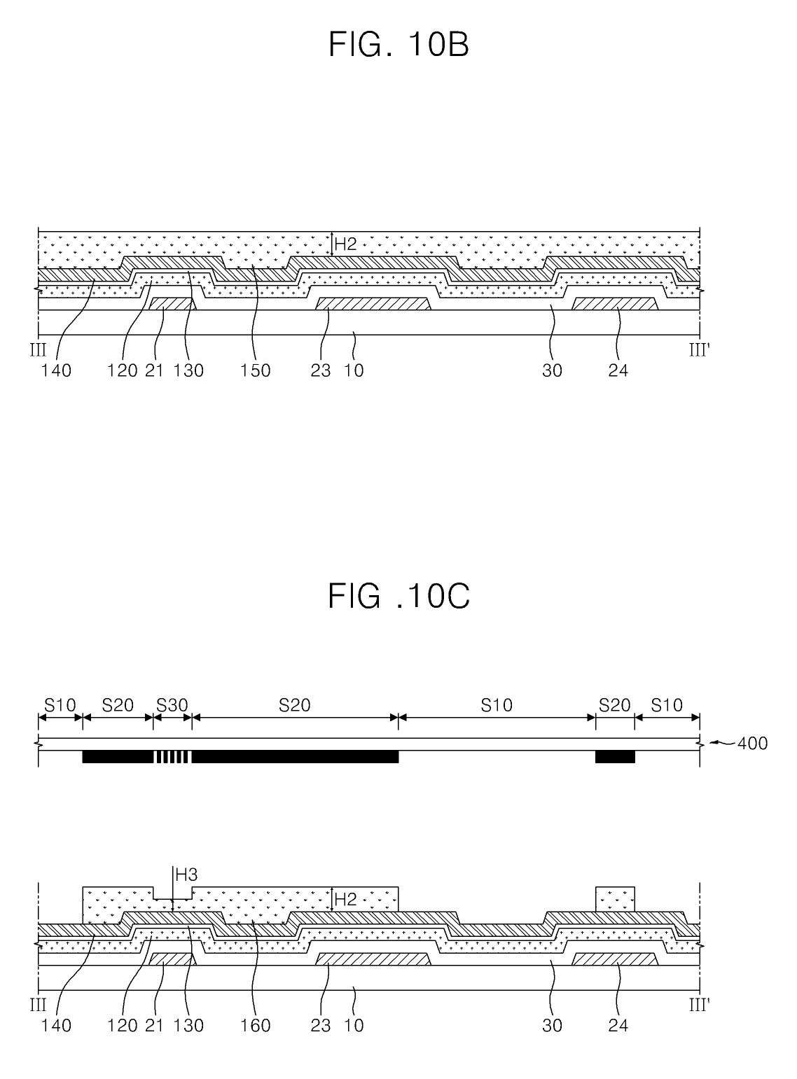

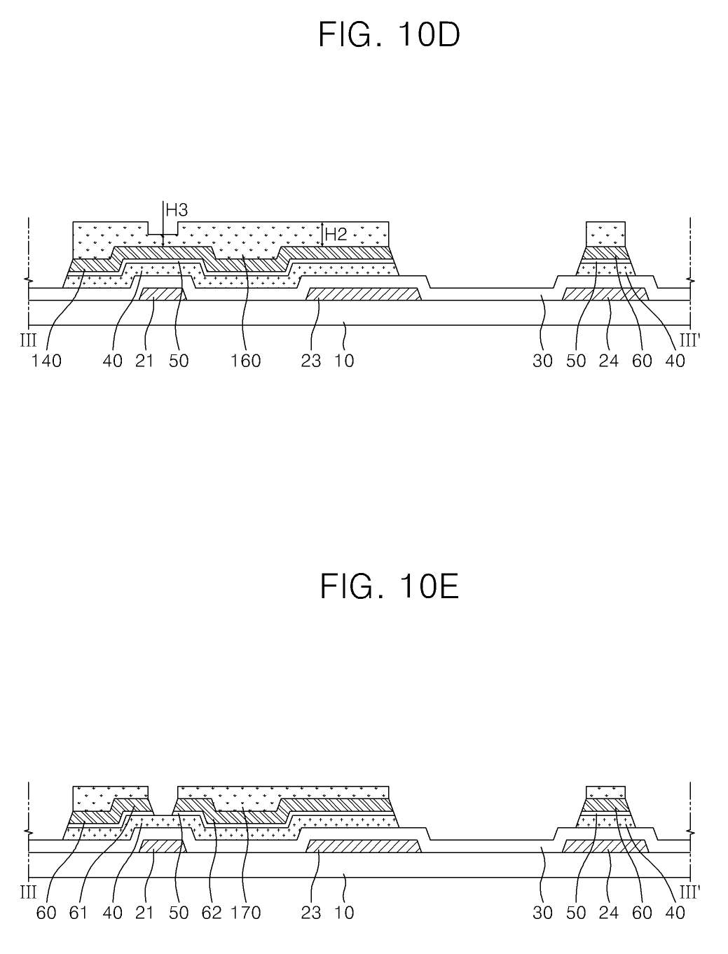

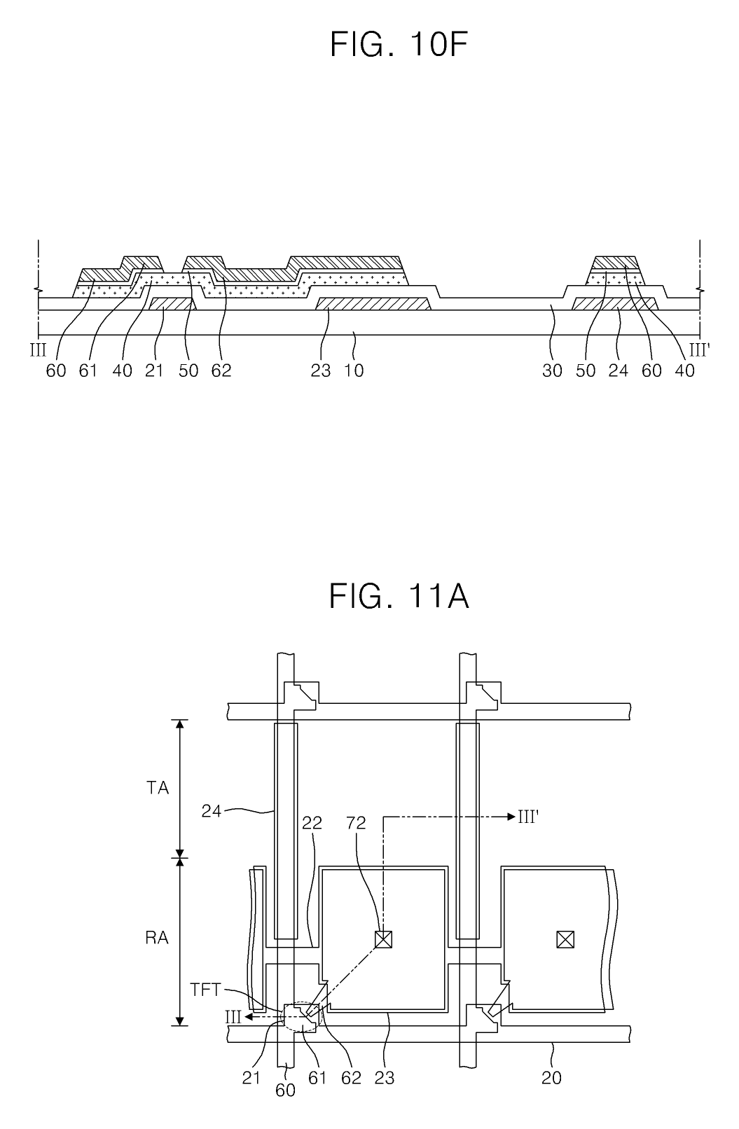

When the gate pattern is formed, a light shielding layer 24 may be formed to prevent light leakage. In this instance, the light shielding layer 24 is formed to overlap a data line 60 which will be formed later and to be electrically insulated from the storage line 22. The light shielding layer preferably has the width of about 12.5 μm to about 15.5 μm. FIG. 10A is a plan view illustrating a second mask process for manufacturing the TFT array substrate according to the exemplary embodiments of the present invention, and FIG. 10B to 10F are cross-sectional views illustrating the second mask process for manufacturing the TFT array substrate according to the exemplary embodiments of the present invention, taken along line III-III′ of FIG. 10A.

Referring to FIGS. 10A and 10F, a gate insulating layer 30 is formed over the whole surface of the lower substrate 10 having the gate pattern, and a semiconductor layer 40 for forming a channel of the TFT and a data pattern are formed on the gate insulating layer 30. The data pattern includes a data line 60, a source electrode 61 electrically connected to the data line 60, and a drain electrode 62 formed to face the source electrode 61. An ohmic contact layer 50 is formed between the semiconductor layer 40 and the data pattern.

Referring to FIG. 10B, the gate insulating layer 30, an amorphous silicon layer 120, a doped amorphous silicon layer 130, and a data metal layer 41 are sequentially formed over the lower substrate 10 having the gate pattern. Preferably, the gate insulating layer 30, the amorphous silicon layer 120 and the doped amorphous silicon layer 130 are formed by using a plasma enhanced chemical vapor deposition (PECVD) technique, and the data metal layer 140 is formed by using a sputtering technique. The gate insulating layer 30 is made of an insulating material such as silicon oxide (SiOx) and silicon nitride (SiNx), and the data metal layer 140 has a single layer structure or a multi-layer structure made of a metal material such as Mo, Ti, Cu, AlNd, Al, Cr, a Mo alloy, a Cu alloy, and an Al alloy. Then, a first photoresist 150 is coated on the second metal layer 140. The first photoresist 150 is patterned into a first photoresist pattern 160 by a photolithography process using a second mask 400 as shown in FIG. 10C. As the second mask 400, used is either a slit mask in which a slit pattern is formed in a portion corresponding a channel of the TFT or a transflective mask in which an amount of light transmitted differs in a portion corresponding to a channel of the TFT and a portion corresponding to the data pattern. In this exemplary embodiment of the present invention, the slit mask is used as the second mask 400. The second mask 400 includes a light shielding portion S20, a slit portion S30 and a light transmitting portion S10. The light shielding portion S20 shields ultraviolet rays to form a relatively thick portion of the first photoresist pattern 160 after the light exposure and development process. The light transmitting portion S20 transmits ultraviolet rays to remove a portion of the first photoresist 150 after the light exposure and development process. The slit portion S30 partially transmits ultraviolet rays to form a relative thin portion of the first photoresist patter 160 after the light exposure and development process. The relatively thick portion of the first photoresist pattern 160 corresponding to the light shielding portion S10 has the same height as a height H2 of a region where the data pattern is to be formed, i.e., the height H2 of the first photoresist 150, and the relatively thin portion of the first photoresist pattern 160 corresponding to the slit portion S20, i.e., a region where the channel of the TFT is to be formed has a height H3 lower than the height H2.

That is, the light shielding portions S20 of the slit mask 400 are aligned corresponding to regions where the semiconductor layer 40, the ohmic contact layer 50 and the data pattern are to be formed to shield ultraviolet rays, so that the first photoresist pattern 160 is formed after a development process as shown in FIG. 1C. Subsequently, as shown in FIG. 10D, a portion of the data metal layer 140 which is not covered with the first photoresist pattern 160 is etched by a first etching process, and the doped amorphous silicon layer 130 and the amorphous silicon layer 120 are etched by a second etching process to thereby form an ohmic contact layer 50 and the semiconductor layer 40.

Subsequently, as shown in FIG. 10E, an upper portion of the first photoresist pattern 160 is removed by an ashing process using oxygen plasma, so that the first photoresist pattern 160 becomes thinner and the portion of the first photoresist pattern 160 corresponding to the channel is removed, forming a second photoresist pattern 170. A portion of the data pattern corresponding to the channel is etched by a third etching process using the second photoresist pattern 170 to thereby form the source and drain electrodes 61 and 62 and the data line 60, and a portion of the ohmic contact layer 50 corresponding to the channel is removed by a fourth etching process to thereby expose a portion of the semiconductor layer 40 corresponding to the channel, separating the source and rain electrodes 61 ad 62. Then, as shown in FIG. 10F, the second photoresist pattern 170 is removed, whereby the data pattern including the source and drain electrodes 61 and 62 and the data line 60 and the semiconductor layer 40 with the channel of the TFT are formed, completing the TFT.

Here, the second mask process may be performed such that twice mask processes are performed by using two masks to form the semiconductor layer 40 and the ohmic contact layer 50 and the data pattern.

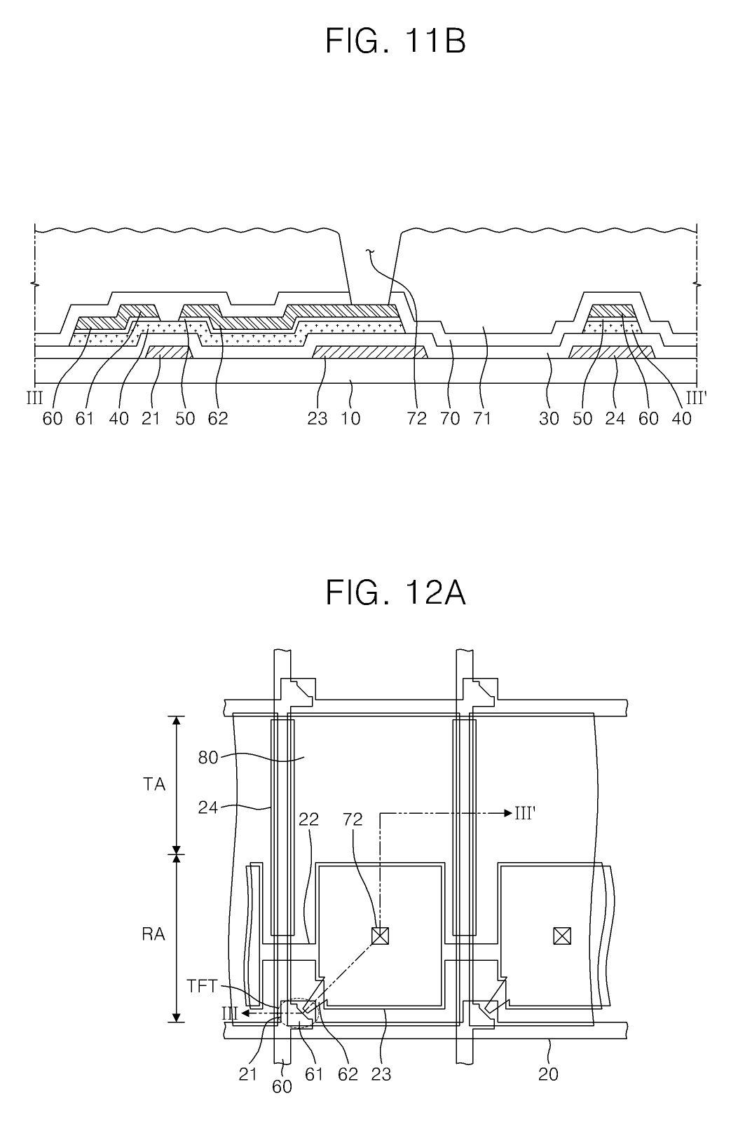

FIG. 11A is a plan view illustrating a third mask process for manufacturing the TFT array substrate according to the exemplary embodiments of the present invention, and FIG. 11B is a cross-sectional view taken along line III-III′ of FIG. 11A.

Referring to FIGS. 11A and 11B, passivation films 70 and 71 with a pixel contact hole 72 formed therein are formed by the third mask process.

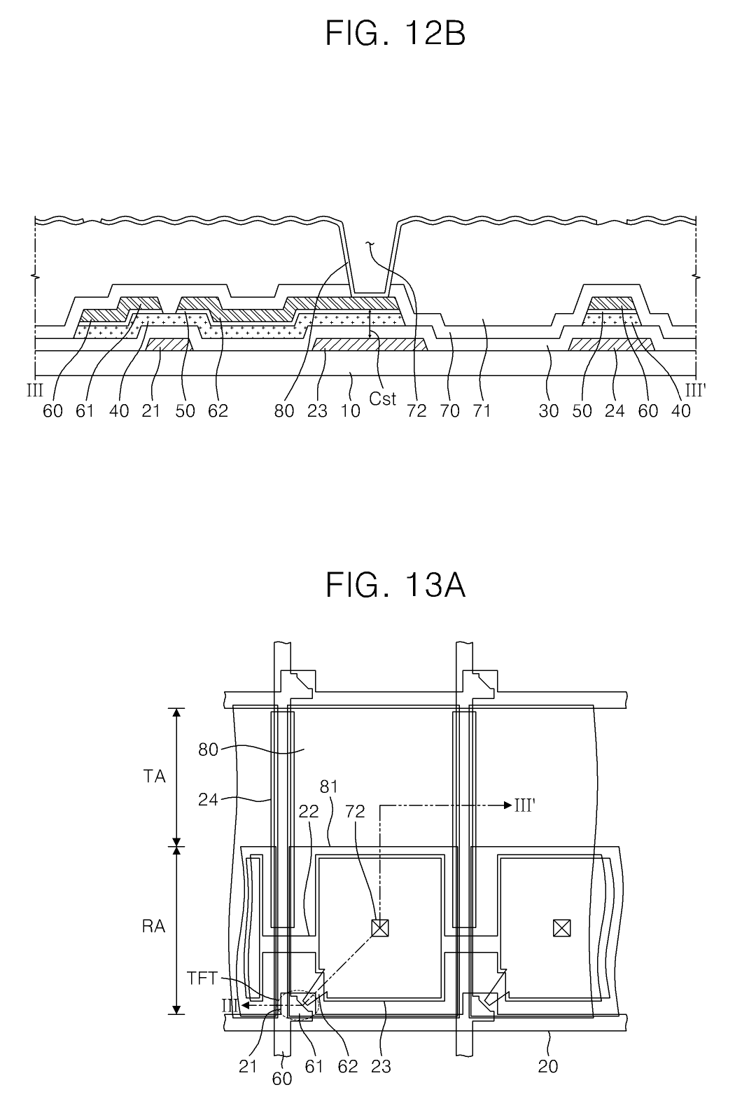

More specifically, an inorganic passivation film 70 is formed over the whole surface of the lower substrate 10 by using a PECVD technique, a spin coating technique, or a spinless coating technique. The inorganic passivation film 70 may be made of the same inorganic insulating material as the gate insulating layer 30. Then, an organic passivation film 71 is formed on the inorganic passivation film 70. The organic passivation film 71 is made of an organic insulating material such as acrylic-based organic compound, benzocyclobutene (BCB) or perfluorocyclobutene (PFCB). A photoresist is coated on the organic passivation film 71 and is exposed to light and developed to thereby form a photoresist pattern. The inorganic and organic passivation films 70 and 71 are etched by an etching process using the photoresist pattern to form a pixel contact hole 72 which penetrates the inorganic and organic passivation films 70 and 71 to expose a portion of the drain electrode 62 of the TFT. Here, any one of the inorganic and organic passivation films 70 and 71 may be formed. FIG. 12A is a plan view illustrating a fourth mask process for manufacturing the TFT array substrate according to the exemplary embodiments of the present invention, and FIG. 12B is a cross-sectional view taken along line III-III′ of FIG. 12A.

Referring to FIGS. 12A and 12B, a pixel electrode 80 is formed by the fourth mask process.

More specifically, a transparent conductive material layer is deposited on the passivation films 70 and 71 by a deposition technique such as a sputtering technique. The transparent conductive material layer is made of indium tin oxide (ITO), tin oxide (TO), and indium zinc oxide (IZO). A photoresist is coated on the transparent conductive material layer, and the conductive material layer is patterned into the pixel electrode 80 by the fourth mask process. The pixel electrode 80 is electrically connected to the drain electrode 62 via the pixel contact hole 72. Preferably, the distance d1 between the two adjacent pixel electrodes 80 is in a range of about 3.5 μm to about 6 μm. The pixel electrode 80 is formed to partially overlap the light shielding layer 24 to increase an aperture ratio. If the organic passivation film is formed, the pixel electrode 80 may be formed to partially overlap the gate line 20 and the data line 60 to thereby further increase an aperture ratio.

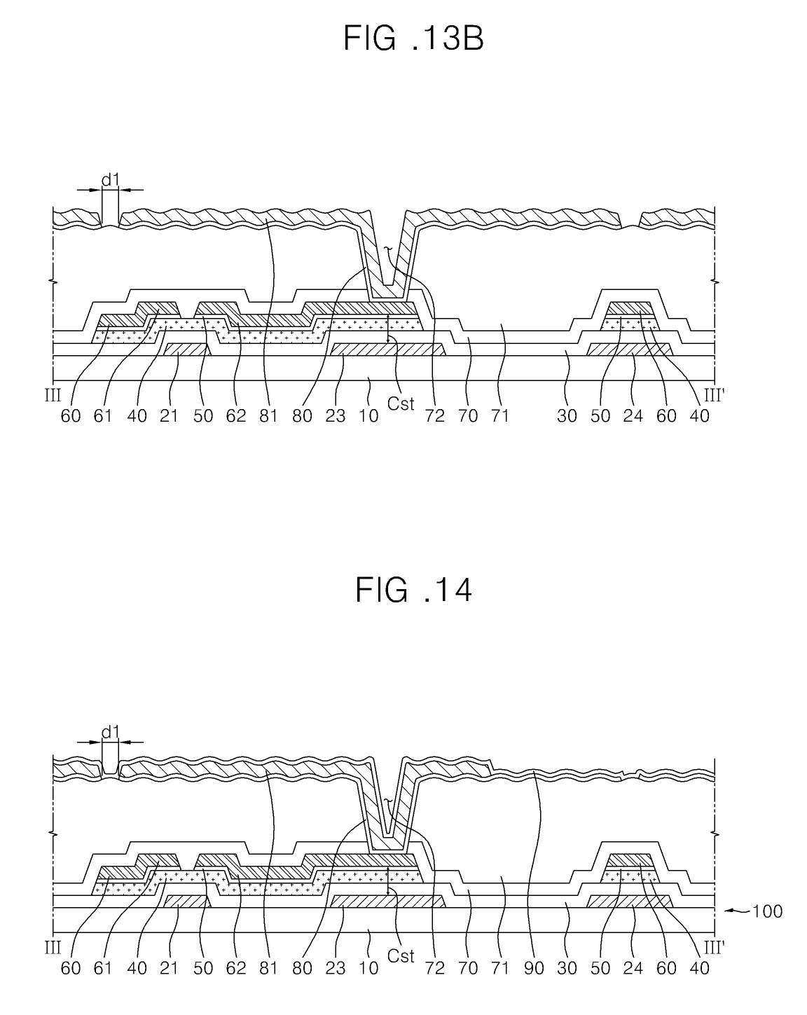

FIG. 13A is a plan view illustrating a fifth mask process for manufacturing the TFT array substrate according to the exemplary embodiments of the present invention, and FIG. 13B is a cross-sectional view taken along line III-III′ of FIG. 13A.

Referring to FIGS. 13A and 13B, the reflective electrode 81 is formed by the fifth mask process.

In more detail, a reflective electrode material layer is formed on the pixel electrode 80. The reflective electrode material layer is made of the same material as the gate pattern or the data pattern. The reflective electrode material layer may be made of an opaque conductive metal with high reflectivity. A photoresist pattern is formed on the reflective electrode material layer, and the reflective electrode material layer is etched by an etching process using the photoresist pattern to thereby form the reflective electrode 81 in the reflective region RA. Preferably, the distance d1 between the two adjacent reflective electrodes is in a range of about 3.5 μm to about 6 μm. That is, the distance d1 between the two adjacent reflective electrodes 81 with the data line 60 interposed therebetween is preferably in a range of about 3.5 μm to about 6 μm. Preferably, the reflective electrode 81 is formed to partially overlap the light shielding layer 24, thereby increasing an aperture ratio. When the organic passivation film is formed, the reflective electrode 81 may be formed to partially overlap the gate line 20 and the data line 60 to thereby further increase an aperture ratio in the reflective region RA.

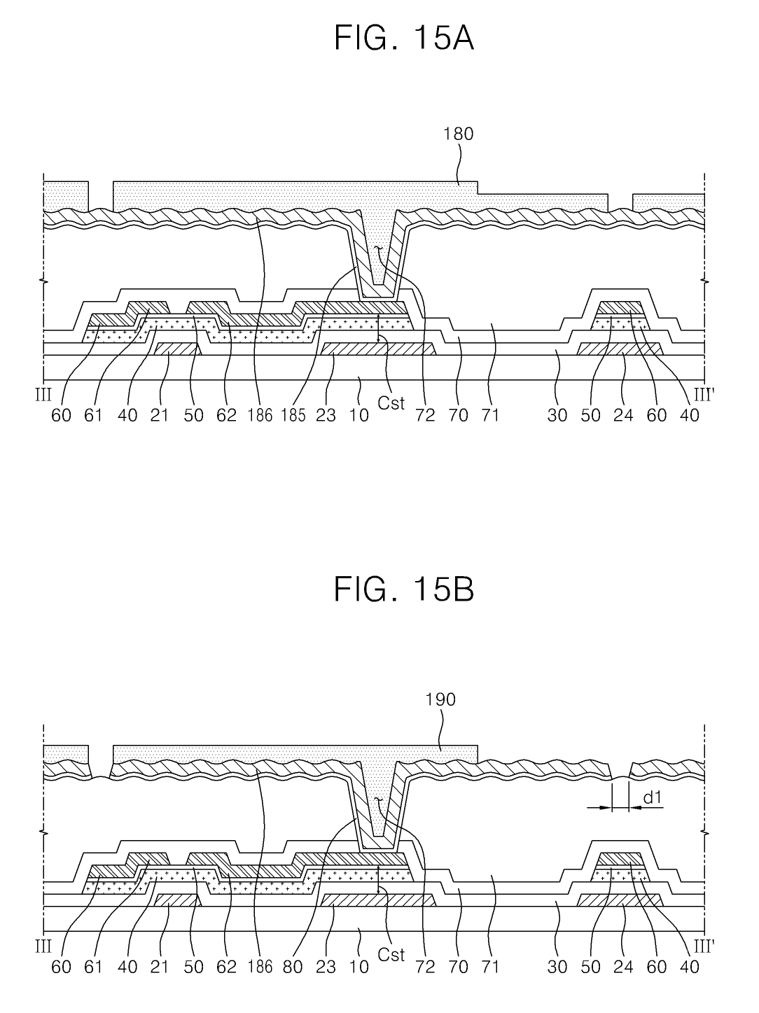

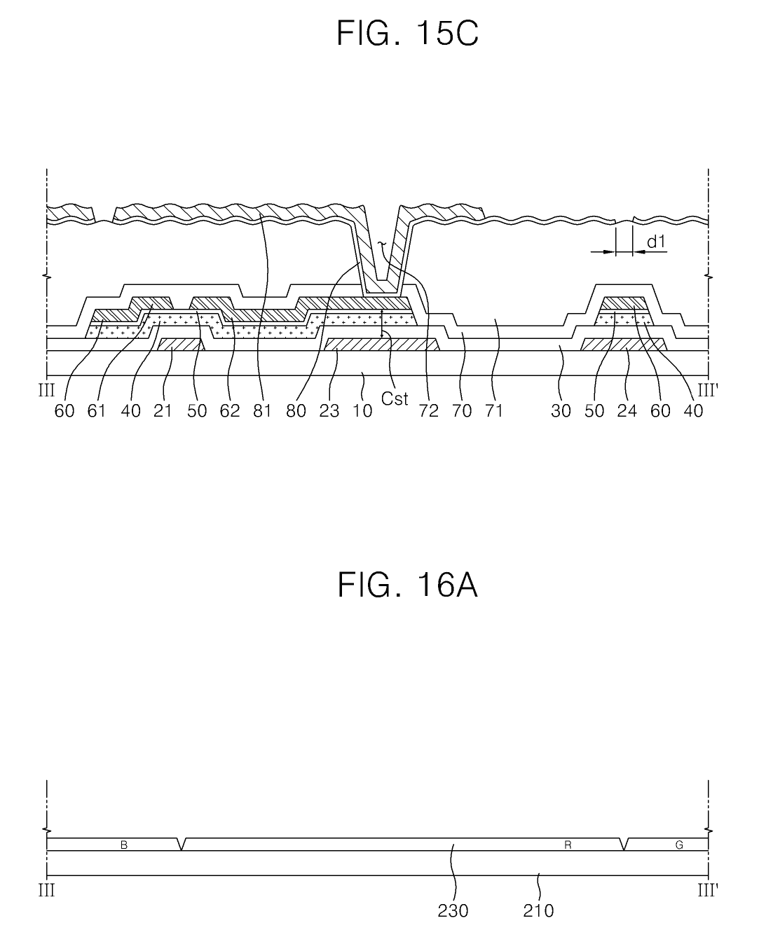

The reflective electrode 81 may be formed before the pixel electrode 80 as shown in FIG. 4. In this instance, the reflective electrode 81 is first formed on the passivation films 70 and 71, and the pixel electrode 80 is formed on the reflective electrode 81. The distance d1 between the two adjacent pixel electrodes 80 and between the two adjacent pixel electrodes 81 is preferably in a range of about 3.5 μm to about 6 μm. As shown in FIG. 14, a lower alignment layer 90 is formed over the whole surface of the lower substrate 10, thereby completing the TFT array substrate 100. Alternatively, the pixel electrode 80 and the reflective electrode 81 may be formed by a single mask process as shown in FIGS. 15A to 15C.

Referring to FIGS. 15A to 15C, the pixel electrode 80 and the reflective electrode 81 are formed by a fourth mask process which is different from the fourth mask process of FIGS. 12A and 12B.

As shown in FIG. 15A, a pixel electrode material layer 185 and a reflective electrode material layer 186 are sequentially deposited on the passivation films 70 and 71 by using, for example, a sputtering technique. The pixel electrode material layer 185 is preferably made of a transparent conductive material such as indium tin oxide (ITO), tin oxide (TO) or indium zinc oxide (IZO). The reflective electrode material layer 186 is preferably made of the same metal as the gate pattern or the data pattern. A third photoresist is formed on the reflective electrode material 186, and the third photoresist is patterned by a fourth mask to form a photoresist pattern 180 which exposes a portion of the reflective electrode material 186. Here, as the fourth mask, a slit mask or a half-tone mask is used. That is, the fourth mask includes a slit or a half-tone corresponding to the transmissive region TA, a photosensitive pattern corresponding to the gate line 20 and the data line 60, and a shielding pattern corresponding to the reflective region RA.

Then, as shown in FIG. 15B, the portions of the pixel electrode and reflective electrode material layers 185 and 186 corresponding to the gate line 20 and the data line 60 are etched by a first etching process using the third photoresist pattern 180. Thereafter, a portion of the third photoresist pattern 180 corresponding to the transmissive region TA is removed by an ashing process to form a fourth photoresist pattern 190. Subsequently, as shown in FIG. 15C, the exposed portion of the reflective electrode material layer 186 is etched by a second etching process using the fourth photoresist pattern 190, and the fourth photoresist pattern 190 is removed, thereby forming the pixel electrode 80 and the reflective electrode 81. The pixel electrode 80 is electrically connected to the drain electrode 62 via the pixel contact hole 72. Preferably, the distance d1 between adjacent pixel electrodes 80 and between the adjacent reflective electrodes 81 is in a range of about 3.5 μm to about 6 μm. Preferably, the pixel electrode 80 partially overlaps the light shielding layer 24 to thereby increase an aperture ratio. Here, if the organic passivation film is used, the pixel electrode 80 may partially overlap the gate line 20 and the data line 60 to thereby further increase an aperture ratio.

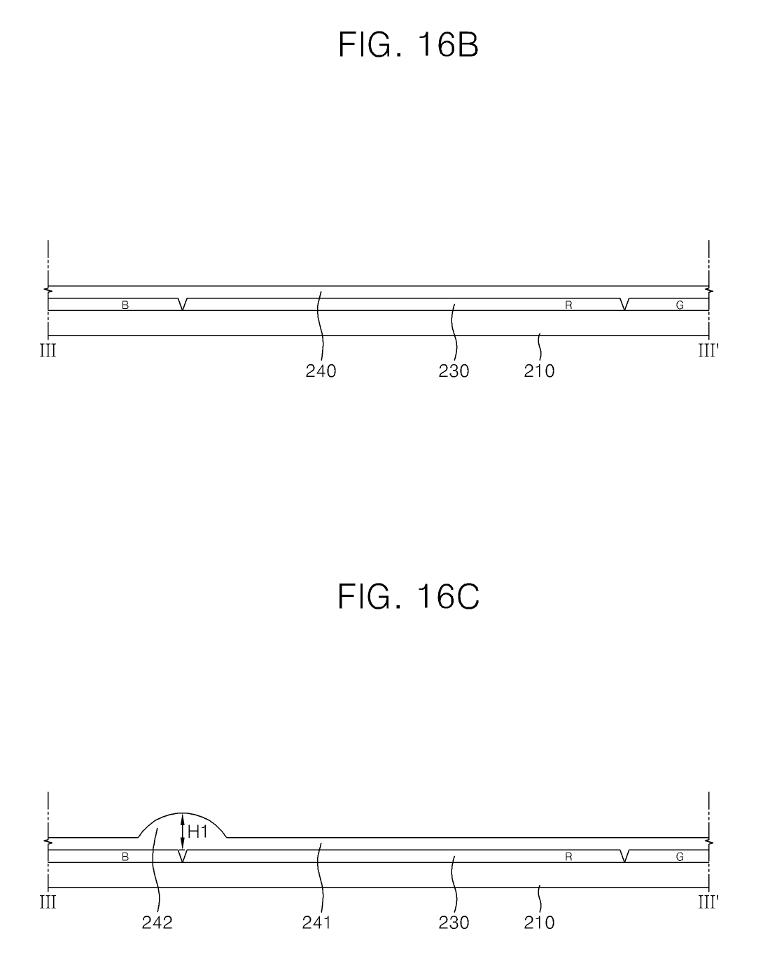

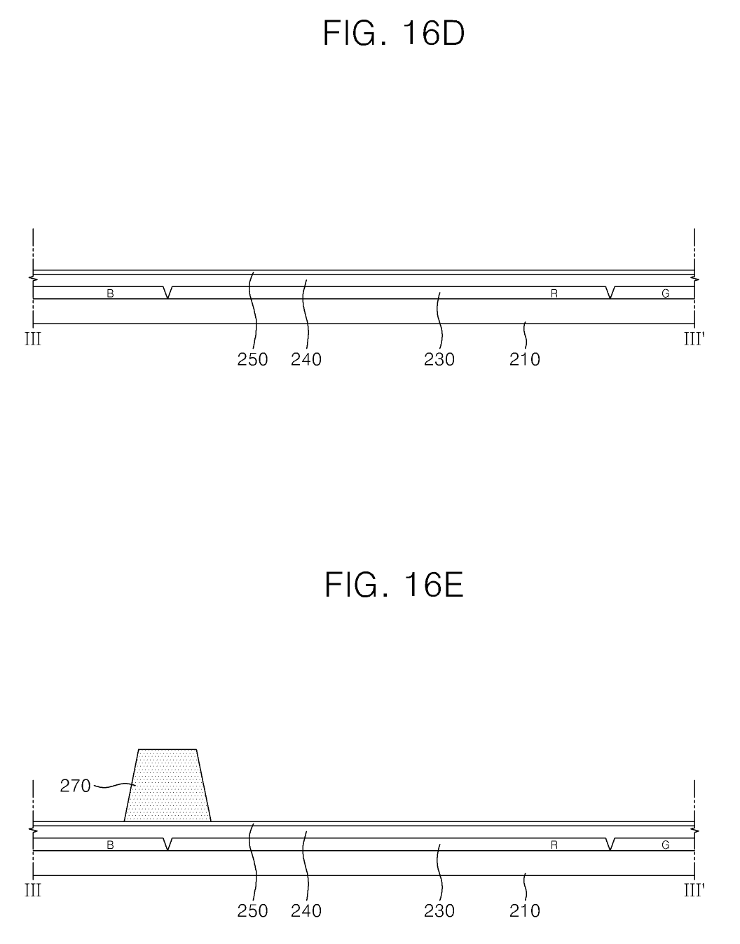

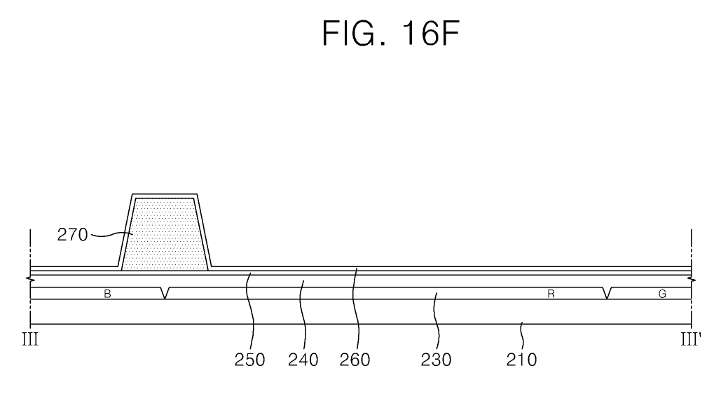

FIGS. 16A to 16F are cross-sectional views illustrating the color filter array substrate according to the exemplary embodiment of the present invention.

Referring to FIG. 16A, a color filter layer 230 is formed on the upper substrate 210. The color filter layer 230 is formed such that a red color layer with negative photosensitivity is coated and is patterned into a red color filter by a photolithography process using a red color filter mask, a green color layer with negative photosensitivity is coated and is patterned into a green color filter by a photolithography process using a green color filter mask, and a blue color layer with negative photosensitivity is coated and is patterned into a blue color filter by a photolithography process using a blue color filter mask.

The color filter layer 230 may be formed by using an ink jet method. That is, the red (R), green (G) and blue (B) color filters may be formed by the ink jet method corresponding to the respective pixel regions.

Referring to FIG. 16B, an organic insulating material is coated over the whole surface of the upper substrate 210 to form an overcoat layer 240. Preferably, the overcoat layer 240 has the thickness of about 0.5 μm to about 2 μm. Here, the overcoat layer 240 has a step portion or a convex portion as shown in FIG. 16C. The overcoat layer 240 includes a first overcoat portion 241 formed on the color filter 230 and the second overcoat portion 242 formed at a location where a column spacer 270 is to be formed. Preferably, the height of the second overcoat portion 242 is equal to or less than about 2 μm. More preferably, the height of the second overcoat portion 242 is in a range of about 1.51 μm to about 1.9 μm.

Referring to FIG. 16D, a common electrode 250 is formed on the overcoat layer 240.

In more detail, a transparent conductive material layer is deposited over the whole surface of the upper substrate 210 as the common electrode 250. Preferably, the transparent conductive material layer is made of a transparent conductive material such as ITO, TO or IZO. The common electrode 250 may be patterned corresponding to the pixel region. Preferably, the common electrode 250 has a thickness of about 800 Å to about 1,500 Å.

Referring to FIGS. 16E and 16F, the column spacer 270 and an upper alignment layer 260 are formed on the common electrode 250.

In more detail, a photosensitive organic insulating material layer is formed on the common electrode 250 and is then patterned into the column spacer 270 by a photolithography process using a column spacer mask. A material such as polyimide is formed over the whole surface of the upper substrate 210 by using a roll printing method or an ink jet method to cover the common electrode 250 and the column spacer 270, thereby forming the upper alignment layer 260. Preferably, the upper alignment layer 260 is formed at the thickness of equal to or less than about 1,000 Å. Thereafter, a pre-tilt angle θ of liquid crystal molecules is formed by a rubbing process.

If the cell gap CG is formed by, for example, a bid spacer other than the column spacer 270, the bid spacer may be formed after the upper alignment layer 260 is formed. Alternatively, the column spacer 270 and the upper alignment layer 260 may be formed of the same material by a single photolithography process.

Before forming the color filter layer 230, a black matrix 220 may be formed.

In this instance, as shown in FIGS. 7 and 8, the black matrix 22 is formed of an opaque metal or opaque organic material on the upper substrate 210, and subsequently, a process for forming the color filter layer 230 is performed.

More specifically, an opaque metal or opaque organic material is formed on the upper substrate 210 and is then patterned into the black matrix 220 which is formed on portions of the upper substrate 210 corresponding to the gate line 20, the data line 60 and the TFT by a mask process. The black matrix 220 is preferably formed to overlap the column spacer 270. More preferably, the column spacer 270 is formed corresponding to the black matrix 220 over the TFT region. The color filter 230 may be formed to partially overlap the black matrix 220.

As described above, the transflective LCD device according to the present invention can prevent an abnormal driving of the liquid crystal layer which is caused by an electric field between the adjacent pixel electrodes or between the adjacent reflective electrodes since the distance between the adjacent pixel electrodes and between the adjacent reflective electrodes is in a range of about 3.5 μm to about 6 μm. Also, since the light shielding layer is formed to overlap the data line, it is possible to prevent an after-image which occurs around the data line due to light leakage. Furthermore, it is possible to prevent an after-image since the cell gap CG is in a range of about 3.5 μm to about 4 μm.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. A thin film transistor (TFT) array substrate, comprising:
a gate line and a data line which cross each other;
a pixel region which has a transmissive region and a reflective region;
a TFT electrically connected to the gate line and the data line;
a pixel electrode formed in the pixel region to be electrically connected to the TFT; and
a reflective electrode formed in the reflective region,
wherein the distance between adjacent pixel electrodes or between adjacent reflective electrodes with the data line interposed therebetween is in the range of about 3.5 to about 6 μm.

2. The TFT array substrate of claim 1, wherein the pixel electrode is formed beneath or on the reflective electrode.

3. The TFT array substrate of claim 1, further comprising, a light shielding layer formed below the data line to overlap the data line and which is wider than the data line.

4. The TFT array substrate of claim 3, wherein the light shielding layer is in the range of about 12.5 μm to about 15.5 μm.

5. A transflective liquid crystal display (LCD) device, comprising:
a first substrate including: a gate line and a data line which cross each other
a pixel region which has a transmissive region and a reflective region;
a TFT electrically connected to the gate line and the data line;
a pixel electrode formed in the pixel region to be electrically connected to the TFT; and
a reflective electrode formed in the reflective region, wherein the distance between the adjacent pixel electrode or between the adjacent reflective electrodes with the data line interposed therebetween is in a range of about 3.5 μm to about 6 μm; and
a second substrate having a color filter and facing the first substrate with a liquid crystal layer interposed therebetween; and
a spacer for maintaining a cell gap between the first and second substrates, the spacer formed in at least one of the first and second substrates.

6. The transflective LCD device of claim 5, wherein the cell gap is in the range of about 3.5 μm to about 4 μm.

7. The transflective LCD device of claim 6, wherein the second substrate comprises a color filter formed corresponding to the pixel region, an overcoat layer formed on the color filter at a location corresponding to the spacer, and a common electrode formed on the overcoat layer to apply a common voltage.

8. The transflective LCD device of claim 7, wherein the thickness of the overcoat layer is in the range of about 1.4 μm to about 2 μm.

9. The transflective LCD device of claim 8, wherein the overcoat layer comprises a first overcoat portion formed on the color filter and a second overcoat portion formed at a location corresponding to the spacer and having the thicker thickness than the first overcoat portion.

10. The transflective LCD device of claim 9, wherein the thickness of the first overcoat portion is in the range of about 1.4 μm to about 2 μm, and the thickness of the second overcoat portion is in the range of about 1.5 μm to about 1.9 μm.

11. The transflective LCD device of claim 10, wherein the spacer formed on the second overcoat portion has a thickness of about 1.7 μm to about 2.1 μm.

12. The transflective LCD device of claim 11, wherein the second substrate further comprises a black matrix formed corresponding to the gate and data lines and the TFT.

13. The transflective LCD device of claim 5, wherein the first substrate further comprises a light shielding layer which overlaps the data line with an insulating layer interposed therebetween and is wider than the data line.

14. The transflective LCD device of claim 13, wherein the width of the light shielding layer is in the range of about 12.5 μm to about 15.5 μm.

15. The transflective LCD device of claim 14, wherein the reflective electrode is formed beneath or on the pixel electrode.

16. The transflective LCD device of claim 15, wherein the first substrate further comprises a storage line formed in parallel to the gate line to supply a storage voltage and a storage electrode formed in the reflective region to overlap the reflective electrode and electrically connected to the storage line.

17. The transflective LCD device of claim 16, wherein the light shielding layer is electrically insulated from the storage line.

18. The transflective LCD device of claim 17, wherein at least one of the pixel electrode and the reflective electrode partially overlap the light shielding layer.

19. The transflective LCD device of claim 7, wherein the first and second substrates further comprise first and second alignment layers for an arrangement of liquid crystal molecules, and the first and second alignment layers have a pre-tilt angle of about 6°.

20. The transflective LCD device of claim 19, wherein the first substrate further comprises a light shielding layer which overlaps the data line with an insulating layer interposed therebetween and has the wider width than the data line.

21. A method for manufacturing a transflective liquid crystal display (LCD) device, comprising:
preparing a first substrate including a gate line and a data line which cross each other; a pixel region which has a transmissive region and a reflective region; a pixel electrode formed in the pixel region to face an adjacent pixel electrode with the data line interposed therebetween; and a reflective electrode formed in the reflective region, wherein a distance between the adjacent pixel electrode or between the adjacent reflective electrodes is in the range of about 3.5 μm to about 6 μm; and
preparing a second substrate having a color filter array and facing the first substrate with a liquid crystal layer interposed therebetween; and
forming a spacer for maintaining a cell gap between the two substrates, the spacer formed in at least one of the first and second substrates.

22. The method of claim 21, wherein the cell gap is in the range of about 3.5 μm to about 4 μm.

23. The method of claim 22, wherein the step of preparing the first substrate further comprises forming a light shielding layer which overlaps the data line and is wider than the data line.

24. The method of claim 23, wherein the light shielding layer is formed of the same material as the gate line on the same plane as the gate line in the step of forming the gate line.

25. The method of claim 21, wherein the step of preparing the first substrate further comprises forming a thin film transistor (TFT), above a lower substrate, which is electrically connected to the gate and data lines and is electrically connected to any one of the pixel electrode and the reflective electrode.

26. The method of claim 25, wherein the step of preparing the first substrate further comprises forming a storage line in parallel to the gate line to supply a storage voltage and forming a storage electrode which is formed in the reflective region to be electrically connected to the storage line and overlaps any one of the pixel electrode and the reflective electrode to form a storage capacitor.

27. The method of claim 26, wherein the step of preparing the first substrate further comprises forming the pixel electrode in the pixel region through a transparent conductive material layer and forming the reflective electrode on the pixel electrode in the reflective region through an opaque conductive material layer.

28. The method of claim 27, wherein in any one of the step of forming the pixel electrode and the step of forming the reflective electrode, at least one of the pixel electrode and the reflective electrode is formed to partially overlap the light shielding layer.

29. The method of claim 21, wherein the step of preparing the second substrate comprises
forming a color filter on an upper substrate at a location corresponding to the pixel region;
forming an overcoat layer for planarizing the color filter on the color filter; and
forming a common electrode for applying a common voltage on the overcoat layer.

30. The method of claim 29, wherein the step of forming the overcoat layer comprises
forming a first overcoat portion at a location corresponding to the pixel region; and
forming a second overcoat portion on a location corresponding to the spacer, the second overcoat portion is thicker in thickness than the first overcoat portion.

31. The method of claim 30, wherein the thickness of the first overcoat portion is in the range of about 1.4 μm to about 2 μm, and the thickness of the second overcoat portion is in the range of about 1.5 μm to about 1.9 μm.

32. The method of claim 31, wherein the thickness of the spacer is in the range of about 1.7 μm to about 2.1 μm, and sum of the thicknesses of the second overcoat portion and the spacer is about 3.6 μm.

33. The method of claim 21, further comprising, after the step of preparing the first substrate and the step of preparing the second substrate:
forming a first alignment layer on the pixel electrode and the reflective electrode;
forming a second alignment layer on the common electrode; and
rubbing any of the first and second alignment layers to form a predetermined pre-tilt angle.
